(19) United States
(12) Patent Application Publication
(10) Pub. No.: US 2025/0228033 A1
(43) Pub. Date: Jul. 10, 2025

(54) METHOD OF MANUFACTURING AN INFRARED DEVICE

(71) Applicant: Asahi Kasei Microdevices Corporation, Tokyo (JP)

(72) Inventor: Taisei NAGAISHI, Tokyo (JP)

(73) Assignee: Asahi Kasei Microdevices Corporation, Tokyo (JP)

(21) Appl. No.: 19/091,819

(22) Filed: Mar. 27, 2025

Related U.S. Application Data
(63) Continuation of application No. 17/645,513, filed on Dec. 22, 2021, now Pat. No. 12,289,929.

(30) Foreign Application Priority Data
Dec. 24, 2020 (JP) 2020-214602
Nov. 4, 2021 (JP) 2021-180604

(51) Int. Cl. H10F 77/14; H10F 30/10; H10F 71/00; H10H 20/01; H10H 20/821

(52) U.S. Cl. CPC H10F 77/147; H10F 30/10; H10F 71/00; H10H 20/01; H10H 20/821

(57) ABSTRACT

A method of manufacturing an infrared device is provided. The method includes: a step of forming a first semiconductor layer of first conductive type on one face side of a substrate; a step of forming a second semiconductor layer serving as an active layer on the first semiconductor layer; a step of forming a third semiconductor layer of second conductive type on the second semiconductor layer; a first etching step of forming a first mesa portion including an upper side portion of the first semiconductor layer, the second semiconductor layer and the third semiconductor layer by applying a dry etching process with an interelectrode voltage 330V or higher; and a second etching step of applying a dry etching process with an interelectrode voltage less than 330V.

### CROSS-REFERENCE TO RELATED APPLICATION

The present application is a continuation application of U.S. patent application Ser. No. 17/645,513 filed Dec. 22, 2021, which claims priority to and the benefit of Japanese Patent Application Nos.2020-214602 (filed on Dec. 24, 2020) and 2021-180604 (filed on Nov. 4, 2021). The disclosures of the prior applications are hereby incorporated by reference herein in their entirety.

### TECHNICAL FIELD

This disclosure relates to infrared devices and a method of manufacturing infrared device light receiving elements.

### BACKGROUND

As an infrared device, an infrared light receiving element that outputs a signal according to the received infrared light and an infrared light emitting element that emits infrared light according to the input power are known. In a quantum infrared light receiving element, infrared light is detected by the photocurrent generated by absorption of infrared light by a semiconductor having a PN junction or a PIN junction. The infrared light receiving element is also referred to as an infrared sensor. Further, the quantum infrared light receiving element is used for human sensors for detecting infrared light emitted from human bodies and non-contact temperature sensors. The infrared light emitting element emits infrared light by a voltage applied in the forward direction. The infrared light emitting element is also referred to as an infrared light emitting diode or an infrared LED. These elements can be used, for example, for a non-dispersive infrared (NDIR) gas sensor (for example, PTL 1). The NDIR gas sensor can measure the gas concentration using an infrared light receiving element that receives infrared light in the absorption wavelength band corresponding to the gas to be detected and an infrared light emitting element that emits infrared light in that absorption wavelength band.

### CITATION LIST

### Patent Literature

PTL 1: JP2004-271518A

### SUMMARY

### Technical Problem

In recent years, infrared devices have become increasingly popular and have a wide range of applications. In particular, in the field of sensing technology, there is a need for sensors with an even higher accuracy, and it is necessary to improve the performance of infrared light receiving elements and infrared light emitting elements. Some quantum infrared light receiving elements and infrared light emitting elements have a pin diode structure of a compound semiconductor using materials such as Al, P, Ga, As, In, and Sb. In this case, photoelectric conversion is performed in an i layer, that is, an active layer, so it is effective to increase the volume of the active layer to improve the photoelectric conversion efficiency.

On the other hand, when the thickness of an i layer is increased in order to increase the volume of the active layer, there arises a processing problem such as deterioration of coating properties of the insulating layer and the electrode portion.

Further, when a compound semiconductor layer is provided on a substrate and a diode shape is formed by the wet etching method, corrosion holes called etch pits are generated on the surface starting from lattice defects introduced between the substrate and the semiconductor layer. Furthermore, when the wet etching method is used, the etching proceeds isotropically, resulting in a formation of a gentle tapered shape on the etching side, and the volume of the active layer is reduced.

It is therefore an object of this disclosure to provide an infrared device with improved photoelectric conversion efficiency and a method of manufacturing an infrared light receiving element of the infrared device.

### Solution to Problem

An infrared device according to an embodiment has a first mesa portion including: a first semiconductor layer of first conductive type provided on one face side of a substrate; a second semiconductor layer serving as an active layer stacked on the first semiconductor layer; and a third semiconductor layer of second conductive type stacked on the second semiconductor layer, wherein,
a lateral surface of the first mesa portion includes a first lateral surface located on the side close to a bottom surface of the first mesa portion, a second lateral surface located above the first lateral surface and a third lateral surface located above the second lateral surface;
a first angle formed by the first lateral surface and one face of the substrate is 0.6° or more and less than 45°, a second angle formed by the second lateral surface and one face of the substrate is 45° or more and 90° or less, and a third angle formed by the third lateral surface and one face of the substrate is 0.6° or more and less than 45°; and
when a length in the direction parallel to the surface of the substrate formed by the first lateral surface is defined as W₁, a length in the direction parallel to the surface of the substrate formed by the second lateral surface is defined as W₂, and a length in the direction parallel to the surface of the substrate formed by the third lateral surface is defined as W₃, W₃/W₂ is 0.15 or more and W₁/W₂ is 0.2 or more and 3.0 or less.

A method of manufacturing an infrared device according to an embodiment includes:
a step of forming a first semiconductor layer of first conductive type on one face side of a substrate;
a step of forming a second semiconductor layer serving as an active layer on the first semiconductor layer;
a step of forming a third semiconductor layer of second conductive type on the second semiconductor layer;
a first etching step of forming a first mesa portion including an upper side portion of the first semiconductor layer, the second semiconductor layer and the third semiconductor layer by applying a dry etching process with an interelectrode voltage 330V or higher; and
a second etching step of applying a dry etching process with an interelectrode voltage less than 330V.

### Advantageous Effect

According to the infrared device of this disclosure, an infrared device with improved photoelectric conversion efficiency and a method of manufacturing an infrared light receiving element of the infrared device can be provided.

### BRIEF DESCRIPTION OF THE DRAWINGS

In the accompanying drawings:

FIG. 1 is a cross-sectional view illustrating a configuration example of an infrared device according to an embodiment;

FIG. 2 is a cross-sectional view schematically illustrating a configuration example of a first mesa portion and a second mesa portion of the infrared device according to an embodiment;

FIG. 3A is a cross-sectional view illustrating a method of manufacturing the infrared device;

FIG. 3B is a cross-sectional view illustrating a method of manufacturing the infrared device;

FIG. 3C is a cross-sectional view illustrating a method of manufacturing the infrared device;

FIG. 3D is a cross-sectional view illustrating a method of manufacturing the infrared device;

FIG. 4 is a diagram illustrating a cross section of an infrared device produced by a method of Comparative Example 1;

FIG. 5 is a chart illustrating derivative values of a shape of a first mesa portion of the infrared device in FIG. 4;

FIG. 6 is a diagram illustrating a cross section of an infrared device produced by a method of Example 1;

FIG. 7 is a chart illustrating derivative values of a shape of a first mesa portion of the infrared device in FIG. 6;

FIG. 8 is a chart in which W₃/W₂ is plotted against V₂;

FIG. 9A is a diagram in which shapes of the first mesa portion are compared under each condition of V₂; and

FIG. 9B is a diagram in which shapes of the first mesa portion are compared under each condition of V₂;

### DETAILED DESCRIPTION

An infrared light receiving element 100 according to an embodiment of this disclosure will be described below using drawings. Here, an infrared light emitting element 200 can be configured with the same configuration as the infrared light receiving element 100 described below. That is, the configuration of the infrared light receiving element 100 described in this embodiment can be a structure of the infrared light emitting element 200 as it is. In other words, in this embodiment, each configuration of these infrared devices will be described by using the infrared light receiving element 100 as a representative. Further, the infrared light emitting element 200 can be manufactured by the same method as a method of manufacturing the infrared light receiving element 100 described below. That is, the method of manufacturing the infrared light receiving element 100 described below can be a method of manufacturing the infrared light emitting element 200 as it is, and together a method of manufacturing the infrared device is described.

In each of the figures described below, the parts corresponding to each other are designated by the same reference signs, and descriptions of the duplicating parts will be omitted as appropriate. Further, this embodiment exemplifies a configuration for embodying the technical idea of this disclosure, and does not specify the material, shape, structure, arrangement, dimensions, etc. of each part to the following. The technical idea of this disclosure can be modified in various ways within the technical scope defined by the claims.

### Infrared Light Receiving Element

### (1) Configuration

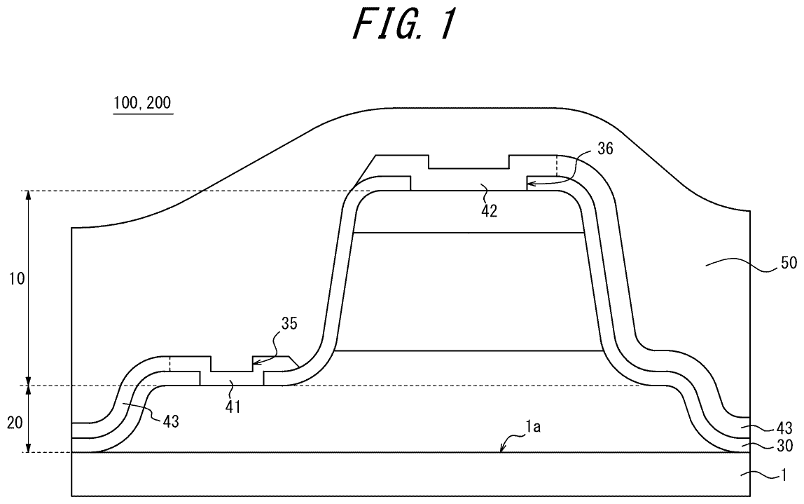

FIG. 1 is a cross-sectional view illustrating a configuration example of an infrared light receiving element 100 according to an embodiment of this disclosure (hereinafter referred to as this embodiment). As illustrated in FIG. 1, the infrared light receiving element 100 includes a first mesa portion 10 provided on one face (hereinafter referred to as a surface) 1a side of a substrate 1, a second mesa portion 20 provided below the first mesa portion 10 on a surface 1a side of the substrate 1, an insulating film 30 that continuously covers the first mesa portion 10 and the second mesa portion 20, a first electrode 41 joined to a top surface of the second mesa portion 20 through a first contact hole 35 provided in the insulating film 30, a second electrode 42 joined to a top surface of the first mesa portion 10 through a second contact hole 36 provided in the insulating film 30, and a wiring portion 43 integrally formed with the first electrode 41 and the second electrode 42. Here, FIG. 1 illustrates a state where a passivation film 50 that covers the infrared light receiving element 100 is provided on the surface 1a side of the substrate 1. The passivation film 50 is an insulating protective film. Here, the boundary surface of the first mesa portion 10 with the second mesa portion 20 may be referred to as a bottom surface of the first mesa portion 10. In FIG. 1, the bottom surface of the first mesa portion 10 is illustrated with a dashed line.

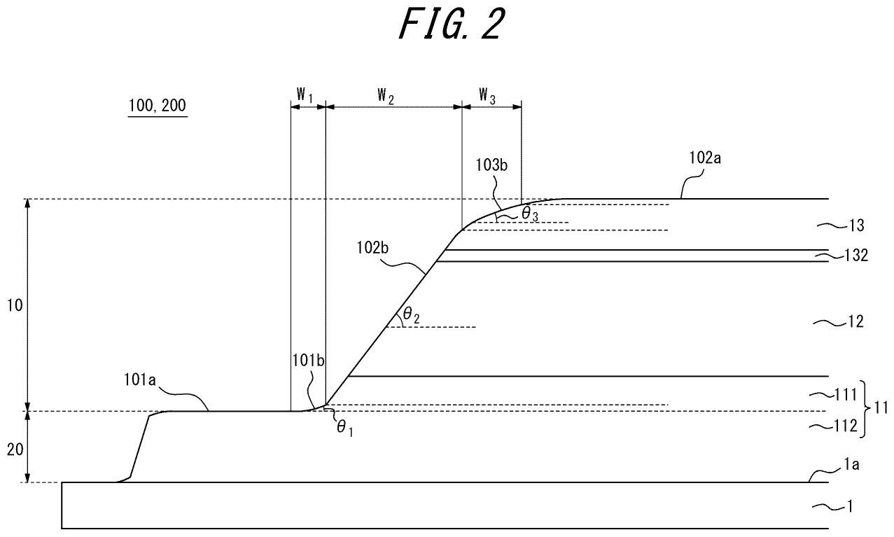

FIG. 2 is a cross-sectional view schematically illustrating a configuration example of the first mesa portion 10 and the second mesa portion 20 of the infrared light receiving element 100. The first mesa portion 10 includes an upper side portion 111 of a first semiconductor layer 11 of first conductive type, a second semiconductor layer 12 stacked on the first semiconductor layer 11 and a third semiconductor layer 13 of second conductive type stacked on the second semiconductor layer 12. Here, the second semiconductor layer 12 is an active layer on which photoelectric conversion is performed. The first semiconductor layer 11 and the third semiconductor layer 13 are a combination of p-type and n-type semiconductor layers. The order of stacking the p-type semiconductor layer and the n-type semiconductor layer does not matter. Here, the wording of “stacked on the first semiconductor layer 11” regarding the second semiconductor layer 12 means that the second semiconductor layer 12 is formed on the first semiconductor layer 11, but this expression also includes the case where another layer is present further between the first semiconductor layer 11 and the second semiconductor layer 12. The same applies to the case where the wording of “on” is used for expressing the relationship of the other layers. For example, another semiconductor layer 132 may be included between the third semiconductor layer 13 and the second semiconductor layer 12. Further, the second mesa portion 20 includes a lower side portion 112 of the first semiconductor layer 11.

The materials of the first semiconductor layer 11, the second semiconductor layer 12 and the third semiconductor layer 13 are not limited. The first semiconductor layer 11, the second semiconductor layer 12 and the third semiconductor layer 13 may contain materials such as Al, P, Ga, As, In and Sb. In addition, the ratio of each element can be adjusted as appropriate. As an example, the first semiconductor layer 11, the second semiconductor layer 12 and the third semiconductor layer 13 may be an In compound, which is a compound containing at least In.

The first mesa portion 10 of this infrared light receiving element 100 includes, in order from the substrate 1 side to the top, a first flat portion 101a, a first lateral surface 101b, a second lateral surface 102b, a third lateral surface 103b, and a second flat portion 102a.

The angle formed by the first flat portion 101a and the surface 1a of the substrate 1 is 0° or more and less than 0.6°. The extension of the first flat portion 101a is the boundary between the upper side portion 111 and the lower side portion 112 of the first semiconductor layer 11.

It is preferable that the first flat portion 101a does not have any corrosion holes with a diameter of 1 μm or more, from a viewpoint of coating properties of the insulating film 30 and the first electrode 41.

When the angle formed by the first lateral surface 101b and the surface 1a of the substrate 1 is defined as a first angle θ₁, the first angle θ₁ is 0.6° or more and less than 45°. The first lateral surface 101b is composed only of a part of the lateral surface of the upper side portion 111 of the first semiconductor layer 11. The first lateral surface 101b is located on the side close to the bottom surface of the first mesa portion 10.

When the angle formed by the second lateral surface 102b and the surface 1a of the substrate 1 is defined as a second angle θ₂, the second angle θ₂ is 45° or more and 90° or less. The second lateral surface 102b is composed of the other part of the lateral surface of the upper side portion 111 of the first semiconductor layer 11, the entire lateral surface of the second semiconductor layer 12, and a part of the lateral surface of the third semiconductor layer 13. That is, the second semiconductor layer 12, which is an active layer, is surrounded entirely by the second lateral surface 102b.

When the angle formed by the third lateral surface 103b and the surface 1a of the substrate 1 is defined as a third angle θ₃, the third angle θ₃ is 0.6° or more and less than 45°. The third lateral surface 103b is composed only of the other part of the lateral surface of the third semiconductor layer 13.

The angle formed by the second flat portion 102a and the surface 1a of the substratel is 0° or more and less than 0.6°. The second flat portion 102a is the top portion of the first mesa portion 10.

In this manner, the first mesa portion 10 has at least two flat portions and 3-stage tapered shape.

The length in the direction parallel to the surface 1a of the substrate 1 formed by the second lateral surface 102b is defined as W₂, and the length in the direction parallel to the surface 1a of the substrate 1 formed by the third lateral surface 103b is defined as W₃. Here, in order to increase the volume of the second semiconductor layer 12, which is an active layer, and improve the light receiving efficiency, θ₂ should be increased and W₂ should be reduced. Furthermore, in the manufacturing process of the infrared light receiving element 100, in order to improve the coating properties of the insulating film 30 and the wiring portion 43 on the upper part of the first mesa portion 10, θ₃ should be reduced and W₃ should be increased. Therefore, if W₃/W₂ is increased, the light receiving efficiency and the coating properties of the insulating film 30 and the wiring portion 43 can be improved at the same time. The W₃/W₂ of the infrared light receiving element 100 according to this embodiment is 0.15 or more. The upper limit is not particularly limited, but may be 1.0 or less, and may be 0.65 or less from the viewpoint of the manufacturing process.

The length in the direction parallel to the surface 1a of the substrate 1 formed by the first lateral surface 101b is defined as W₁. Here, if W₁ is large, the distance between the first contact hole 35 formed on the first flat portion 101a and the second semiconductor layer 12, which is an active layer, is increased, and the percentage of the volume of the active layer in the infrared light receiving element 100 is reduced, and as a result, the light receiving efficiency is reduced. Here, if W₁/W₂ is reduced, the percentage of the volume of the active layer in the infrared light receiving element 100 is increased, and the light receiving efficiency can be improved. On the other hand, if W₁/W₂ is extremely small, the coating properties of the insulating film 30 is impaired, so it is preferable that W₁/W₂ is 0.1 or more. The W₁/W₂ of the infrared light receiving element 100 according to this embodiment is 0.2 or more and 3.0 or less. Here, the above description of the light receiving efficiency is applied to the light emitting efficiency of the infrared light emitting element 200, which has the same structure as the infrared light receiving element 100.

The light receiving efficiency is improved when θ₂ is increased and W₂ is reduced, but when θ₂ is large, the coating properties of the insulating film 30 and the wiring portion 43 on the second lateral surface 102b are reduced. Thus, it is preferable that θ₂ is 45° or more and 75° or less. The θ₂ of the infrared light receiving element 100 according to this embodiment may be 45° or more and 75° or less.

The shape of the second mesa portion 20 provided below the first

mesa portion 10 is not particularly limited. From the second mesa portion 20 to the substrate 1 may be of any shape.

### (2) Manufacturing Method

Next, a method of manufacturing the infrared light receiving element 100 illustrated in FIG. 2 will be described.

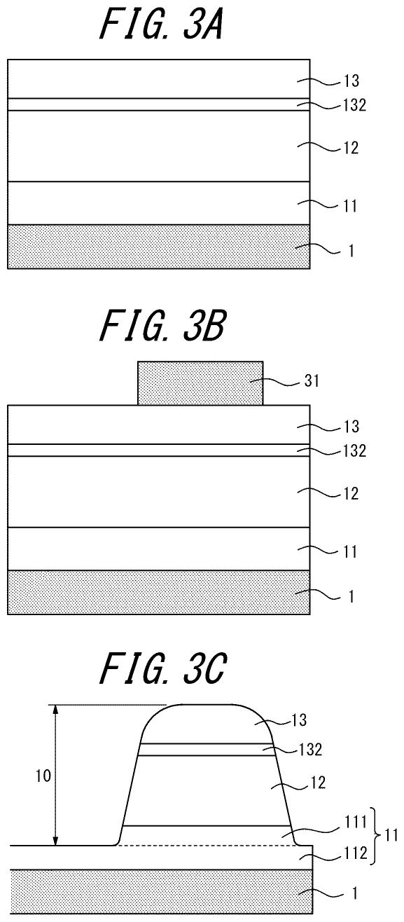

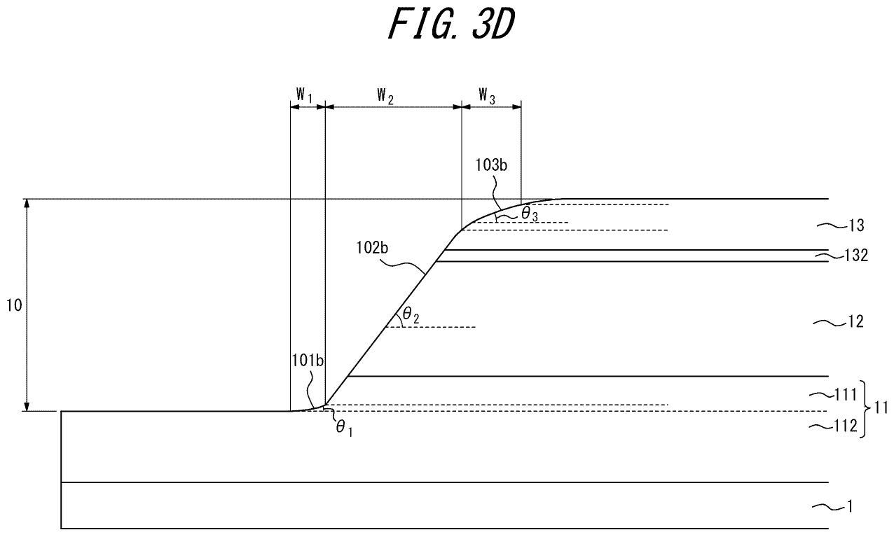

FIGS. 3A, 3B and 3C are cross-sectional views illustrating a method of manufacturing the infrared light receiving element 100 according to this embodiment in the order of steps.

### (2.1) Step of Stacking Semiconductors

As illustrated in FIG. 3A, first, the first semiconductor layer 11 of first conductive type is formed on the surface side of the substrate 1. Next, the intrinsic second semiconductor layer 12 is formed on the first semiconductor layer 11. Then, the third semiconductor layer 13 of second conductive type is formed on the second semiconductor layer 12. That is, the first semiconductor layer 11, the second semiconductor layer 12 and the third semiconductor layer 13 are deposited in this order on the substrate 1. The deposition of the first semiconductor layer 11, the second semiconductor layer 12 and the third semiconductor layer 13 is continuously performed, for example, in the chamber of the epitaxial growth apparatus while maintaining the preset vacuum level.

### (2.2) Step of Forming a First Mesa Portion

Next, as illustrated in FIG. 3B, a resist pattern 31 is formed on the third semiconductor layer 13 using photolithography technology. Before a masking step of forming a mask of a resist pattern 31, a hard mask such as SiO₂ may be formed on the third semiconductor layer 13 to prevent the resist pattern 31 from directly contacting the third semiconductor layer 13.

Then, the third semiconductor layer 13, the second semiconductor layer 12 and the upper side portion 111 of the first semiconductor layer 11 are dry etched in order by using the resist pattern 31 as a mask. In this dry etching process, a first etching step in which the interelectrode voltage in the dry etching apparatus is 330 V or more and a second etching step in which the interelectrode voltage is 120 V or more and less than 330 V are continuously performed. In this manner, as illustrated in FIG. 3C, the first mesa portion 10 is formed. Hereinafter, the interelectrode voltage in the etching apparatus in the first etching step is expressed as V₁, and the interelectrode voltage in the etching apparatus in the second etching step is expressed as V₂.

In this step of forming the first mesa portion 10, as etching gas for etching the third semiconductor layer 13, the second semiconductor layer 12, and the upper side portion 111 of the first semiconductor layer 11, either halogen gas or a gas that contains halogen in its composition (hereinafter referred to as halogen based gas), or a mixture of these gases is used. An example of halogen gas is chlorine gas (Cl₂). Further, examples of halogen based gas include hydrogen chloride gas (HCl), hydrogen bromide gas (HBr), and the like.

In the method of manufacturing the infrared light receiving element 100 according to this embodiment, the etching gas does not include a gas having an oxidizing action such as oxygen gas. Thus, in the etching step of forming the first mesa portion 10, the selection ratio between the resist and the semiconductor layer is improved, and disappearance of the resist in the etching step can be prevented.

FIG. 3D illustrates the details of the shape of the first mesa portion 10 in FIG. 3C. If V₁ is high, θ₂ can be increased, that is, W₂ can be decreased. Further, if V₂ is low, W₃ can be increased.

### Comparative Example 1

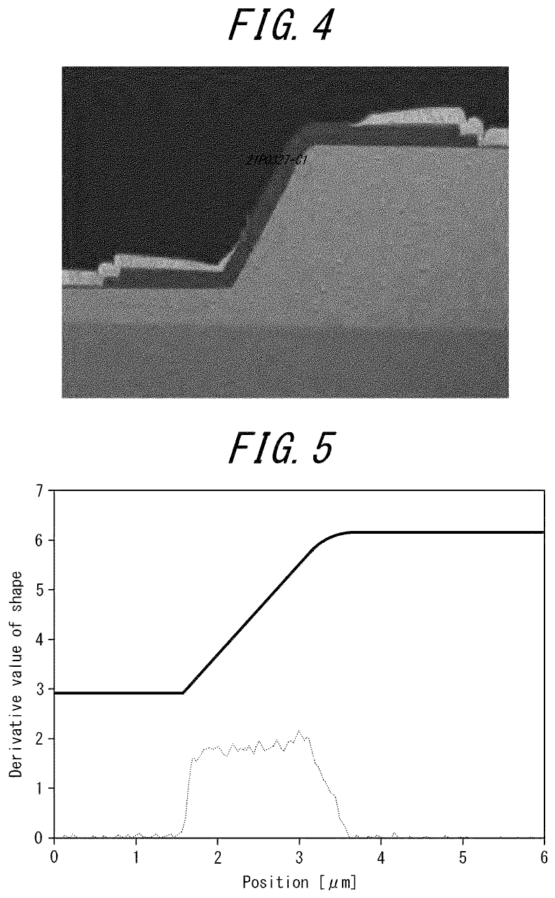

FIG. 4 is an electron micrograph of a cross section of the infrared light receiving element 100 that forms the first mesa portion 10. In Comparative Example 1, a total thickness of 3.6 μm of an InSb n-type semiconductor layer, an intrinsic semiconductor layer and a p-type semiconductor layer were deposited on a GaAs substrate, which was applied with a photoresist “THMR-ip5700HP” manufactured by Tokyo Ohka Kogyo Co., Ltd. to obtain a thickness of 3.5 μm and exposed to form a photoresist pattern. Then, the first etching step was carried out using chlorine gas with V₁ set to 740 V, and the second etching process was carried out continuously using chlorine gas with V₂ set to 740 V without changing the interelectrode voltage in the dry etching apparatus. The Helios 650 manufactured by FEI was used for electron microscope observation, and observation was performed at an acceleration voltage of 2.0 kV at 20,000-fold magnification.

The solid line in FIG. 5 shows the result of extracting the shape of the surface of the first mesa portion 10 in FIG. 4 with an image processing software, ImageJ (open source software, version 1.52u17 was used). Here, the following [1], [2], [3], and [4] were performed as the procedure for extracting the shape:
[1] The Find Edges process for emphasizing sudden changes in brightness in the electron micrographs;
[2] Gaussian Blur process for smoothing the images. At this time, the standard deviation of the Gaussian function can be set to any value corresponding to the electron micrograph;
[3] Threshold process and Clear process for unnecessary areas other than the shape to be extracted. Only the shape to be extracted was specified as the foreground color; and
[4] Analyze Line Graph process for obtaining the coordinate information of the shape to be extracted that was specified as the foreground color.

Further, the dashed line in FIG. 5 shows the result of differentiating the extracted shape of the surface of the first mesa portion 10 with respect to the direction parallel to the surface 1a of the substrate 1 (hereafter referred to as the derivative values of the shape).

Here, the first lateral surface 101b in the first mesa portion 10 is a part where the first angle θ₁ is 0.6° or more and less than 45°, thus is a part located between the point where the derivative value of the shape will be 0.01 (tan (0.6°)( or more for the first time to the point where it will be 1 (tan (45°)) or more, with respect to the direction of the first mesa portion 10. Since the second lateral surface 102b in the first mesa portion 10 is a part located above the first lateral surface 101b and where the second angle θ₂ is 45° or more and less than 90°, thus is a part located between the end point of the first lateral surface 101b and the point where the derivative value of the shape is less than 1. Since the third lateral surface 103b in the first mesa portion 10 is a part located above the second lateral surface 102b and where the third angle θ₃ is 0.6° or more and less than 45°, thus is a part located between the end point of the second lateral surface 102b and the point where the derivative value of the shape is 0.01 or less with respect to the direction of the first mesa portion 10. In this manner, the start point and the end point of the first lateral surface 101b, the second lateral surface 102b and the third lateral surface 103b can be clearly defined using derivative values of the shape.

The ratio of the length W₂ in the direction parallel to the surface 1a of the substrate 1 formed by the second lateral surface 102b and the length W₃ in the direction parallel to the surface 1a of the substrate 1 formed by the third lateral surface 103b, W₃/W₂, obtained by the above procedure, was 0.14. Further, the ratio of W₂ to the length Wi in the direction parallel to the surface 1a of the substrate 1 formed by the first lateral surface 101b, W₁/W₂, was 0.90.

### Example 1

The infrared light receiving element 100 was obtained in the same manner as in Comparative Example 1 except that V₂ was set to 190V.

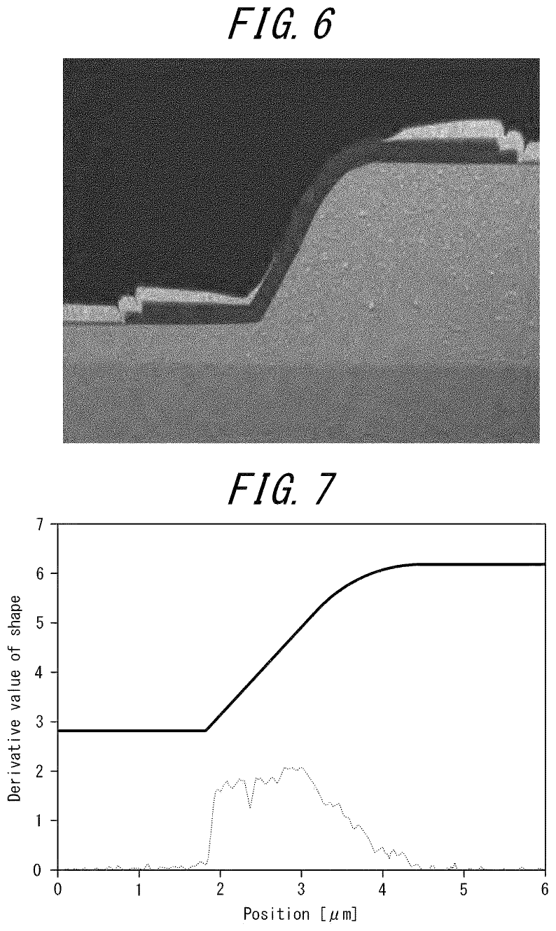

FIG. 6 is an electron micrograph of a cross section of the infrared light receiving element 100. Further, the solid line in FIG. 7 shows the result of extracting the shape of the surface of first mesa portion 10 in FIG. 6 by the same procedure as in Comparative Example 1 using the image processing software ImageJ. The dashed line in FIG. 7 shows the result of differentiating the shape of the surface of the extracted first mesa portion 10 with respect to the direction parallel to the surface 1a of the substrate 1. At this time, when W₃/W₂ was obtained by the same procedure as in Comparative Example 1, W₃/W₂ was 0.51. Further, when W₁/W₂ was obtained, it was 1.06.

### Comparative Example 2

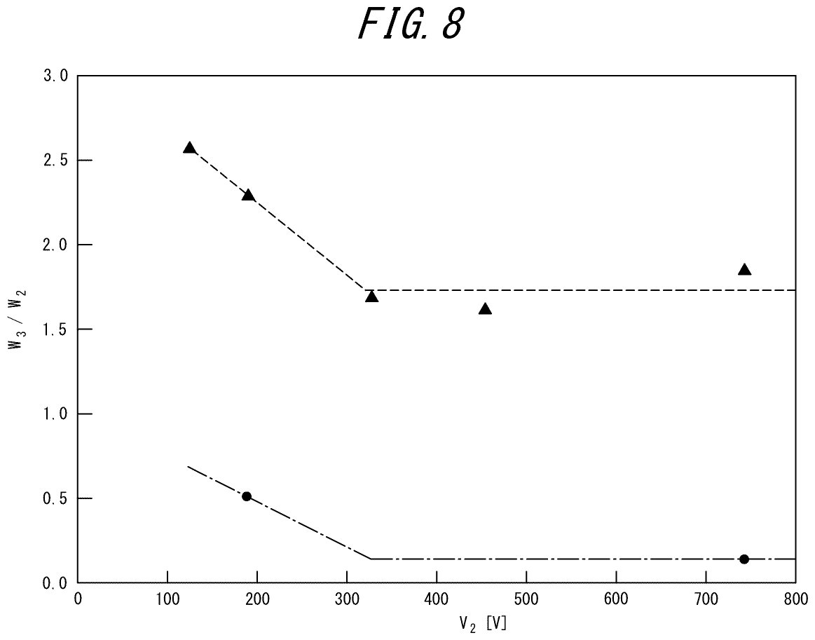

The black triangles in FIG. 8 show the results of W₃′/W₂ obtained by extracting the shape of the surface by creating the infrared light receiving element 100 in the same manner as in Comparative Example 1, and by scanning the first mesa portion 10 immediately after the dry etching process using a laser microscope OLS4000 manufactured by OLYMPUS. A 100× objective lens was used for scanning the first mesa portion 10. The shooting mode was performed under the condition of high precision mode. When V₂ was set to 740 V, W₃′/W₂′ obtained by a laser microscopy was 1.86.

Further, the infrared light receiving element 100 was obtained by the same method as in Comparative Example 2 except that V₂ was set to 450V and 330V. At this time, W₃′/W₂′ obtained by measurement with a laser microscope when V2 was 450 V and 330 V was 1.63 and 1.71.

### Example 2

The infrared light receiving element 100 was obtained by the same method as in Comparative Example 2 except that V₂ was set to 190V and 120V, and W₃′/W₂′ was calculated by a laser microscope in the same manner as in Comparative Example 2. In this case, W₃′/W₂′ was 2.29 and 2.57 when V₂ was 190V and 120V.

From the results of Comparative Example 2 and Example 2 (black triangles and dashed line in FIG. 8), it can be seen that when V₂ is 330V or more, W₃′/W₂′ is not dependent on V₂, but when V₂ is 120V or more and less than 330V, W₃′/W₂′ increases linearly with a negative correlation to V₂ (dashed line in FIG. 8). Here, considering the result of W₃/W₂ obtained from the electron micrograph in Comparative Example 1 (black circle and alternate long and short dash line in FIG. 8), W₃/W₂ is 0.14 when V₂ is 330 V or more. Further, considering the result of W₃/W₂ obtained from the electron micrograph in Example 1, W₃/W₂ is at least 0.15 or more when V₂ is less than 330 V. Further, since W₃/W₂ linearly increases with a negative correlation with V₂ in the range where V₂ is 120V or more and less than 330V, it can be calculated that W₃/W₂ is 0.65 when V₂ is 120V (dashed-dotted line in FIG. 8). That is, when V₂ is 120V or more and less than 330V, W₃/W₂ is 0.15 or more and 0.65 or less.

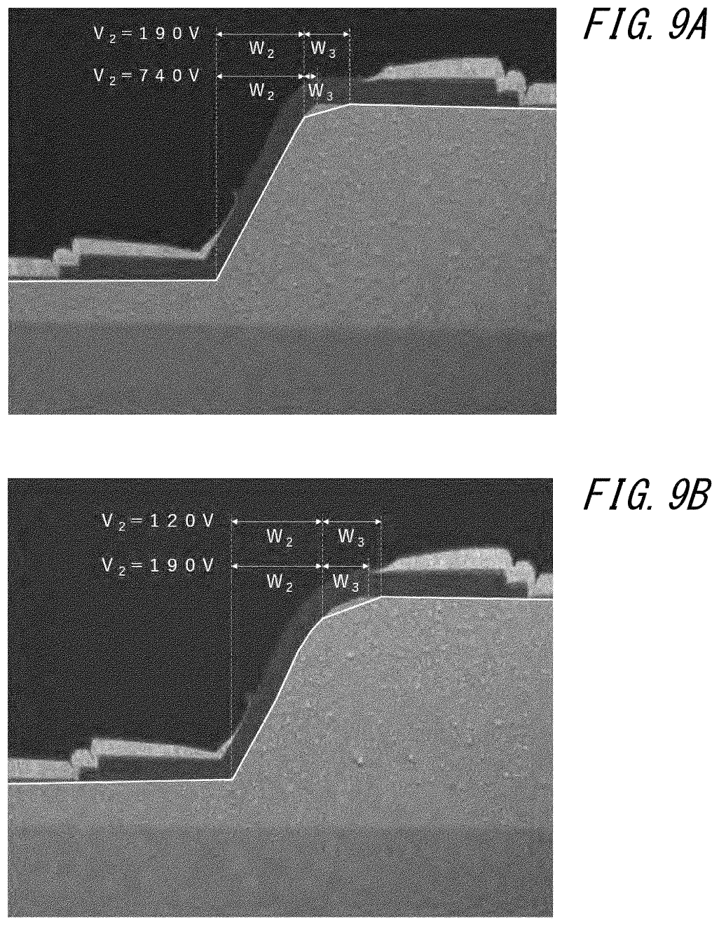

FIGS. 9A and 9B illustrate the results of comparing the shape of the first mesa portion 10 (electron micrographs in the figures) when V₂ is set to 740 V and 190 V, respectively, and the shape of the first mesa portion 10 (white line in the figures) when V₂ is set to 190 V and 120 V, respectively, as illustrated in Comparative Example 1. In this manner, when V₂ is set to 120V or more and less than 330V, W₃/W₂ can be increased.

In any of the above described embodiments, θ₂ is 45° or more and 75° or less. For example, when V₂ illustrated in FIG. 9B is 190V, θ₂ is 54°.

Further, in any of the above described embodiments, the surface of the first mesa portion 10 is flat. No corrosion hole with a diameter of 1 μm or more, called etch pit, which is introduced when forming a mesa shape by the wet etching method, is observed.

### Effects of This Embodiment

The infrared light receiving element 100 according to this embodiment produces the following effects.

As illustrated in FIG. 2, since the second semiconductor layer 12, which is an active layer, is included in the second lateral surface 102b having a steep slope, the volume of the second semiconductor layer 12 can be increased. Therefore, the efficiency of photoelectric conversion is increased, and the infrared light receiving efficiency can be improved.

In addition, since the third lateral surface 103b with a gentle slope is located on the top of the first mesa portion 10, the coating properties (i.e., step coverage) of the insulating film 30 and the wiring portion 43 at the top of the first mesa portion 10 can be improved.

Further, since W₃/W₂, which is the ratio of the length W₃ in the direction parallel to the surface 1a of the substrate 1 formed by the third lateral surface 103b, which is located at the upper part of the first mesa portion 10, to the length W₂ in the direction parallel to the surface 1a of the substrate 1 formed by the second lateral surface 102b is 0.15 or more and 0.65or less, the percentage of the volume of the active layer in the infrared light receiving element 100 can be increased. Therefore, the efficiency of photoelectric conversion is increased, and the infrared light receiving efficiency can be improved.

Further, since W₁/W₂, which is the ratio of the length W₁ in the direction parallel to the surface 1a of the substrate 1 formed by the first lateral surface 101b, which is located at the lower part of the first mesa portion 10, to the length W₂ in the direction parallel to the surface 1a of the substrate 1 formed by the second lateral surface 102b is 0.2 or more and 3.0 or less, the percentage of the volume of the active layer in the infrared light receiving element 100 can be increased. Therefore, the efficiency of photoelectric conversion is increased, and the infrared light receiving efficiency can be improved.

Further, the infrared light emitting element 200 according to this embodiment having the same structure as the infrared light receiving element 100 produces the above described effects in the same manner as the infrared light receiving element 100. However, the “light receiving efficiency” in the above effect is replaced with the “light emitting efficiency.”

1. A method of manufacturing an infrared device, comprising:
a step of forming a first semiconductor layer of first conductive type on one face side of a substrate;
a step of forming a second semiconductor layer serving as an active layer on the first semiconductor layer;
a step of forming a third semiconductor layer of second conductive type on the second semiconductor layer;
a first etching step of forming a first mesa portion including an upper side portion of the first semiconductor layer, the second semiconductor layer and the third semiconductor layer by applying a dry etching process with an interelectrode voltage 330V or higher; and
a second etching step of applying a dry etching process with an interelectrode voltage less than 330V.

2. The method of manufacturing an infrared device according to claim 1, wherein the second etching step applies a dry etching process with an interelectrode voltage 120V or more and less than 330V.

3. The method of manufacturing an infrared device according to claim 1, further comprising a mask step of forming a mask of resist pattern on the third semiconductor layer between the step of forming the third semiconductor layer and the first etching step.

4. The method of manufacturing an infrared device according to claim 3, further comprising a step of forming a hard mask on the third semiconductor layer.

5. The method of manufacturing an infrared device according to claim 1, wherein an etching gas in the first etching step and the second etching step is either one of halogen gas or halogen-based gas, or a mixture thereof.

6. The method for manufacturing an infrared device according to claim 5, wherein the etching gas in the first etching step is a halogen gas, and the halogen gas is chlorine gas.

7. The method for manufacturing an infrared device according to claim 5, wherein the etching gas in the first etching step is a halogen-based gas, and the halogen-based gas is hydrogen chloride gas or hydrogen bromide gas.

8. The method for manufacturing an infrared device according to claim 5, wherein the etching gas in the first etching step does not include oxygen gas.

9. The method for manufacturing an infrared device according to claim 5, wherein the etching gas in the second etching step is a halogen gas, and the halogen gas is chlorine gas.

10. The method for manufacturing an infrared device according to claim 5, wherein the etching gas in the second etching step is a halogen-based gas, and the halogen-based gas is hydrogen chloride gas or hydrogen bromide gas.

11. The method for manufacturing an infrared device according to claim 5, wherein the etching gas in the second etching step does not include oxygen gas.
